(19) United States
(12) Patent Application Publication
(10) Pub. No.: US 2026/0371573 A1
(43) Pub. Date: Nov. 19, 2026

(54) MICROELECTRONIC DEVICES INCLUDING VERTICAL CHANNEL ACCESS DEVICES, AND RELATED MEMORY DEVICES AND ELECTRONIC SYSTEMS

(71) Applicant: Micron Technology, Inc., Boise, ID (US)

(72) Inventors: Kamal M. Karda, Boise, ID (US); Durai Vishak Nirmal Ramaswamy, Boise, ID (US); Yoshinori Ikebuchi, Hiroshima (JP); Eiji Hasunuma, Hiroshima (JP)

(21) Appl. No.: 19/659,068

(22) Filed: Apr. 27, 2026

Related U.S. Application Data
(60) Provisional application No. 63/804,893, filed on May 13, 2025.

(51) Int. Cl. H10B 12/00

(52) U.S. Cl. CPC H10B 12/488; H10B 12/05; H10B 12/315

(57) ABSTRACT

A microelectronic device includes a vertical channel access device including a semiconductor pillar including a first doped region, a channel region vertically above the first doped region, and a second doped region vertically above the channel region. The vertical channel access device further includes a gate electrode horizontally offset from and vertically overlapping the channel region of the semiconductor pillar, and a gate dielectric material horizontally interposed between the gate electrode and the semiconductor pillar. The microelectronic device further includes a conductive contact structure at a vertical position of the second doped region of the semiconductor pillar of the vertical channel access device, the conductive contact structure physically contacting a side surface of the second doped region of the semiconductor pillar.

### CROSS-REFERENCE TO RELATED APPLICATIONS

This application claims the benefit under 35 U.S.C. § 119(e) of U.S. Provisional Patent Application Ser. No. 63/804,893, filed May 13, 2025, the disclosure of which is hereby incorporated herein in its entirety by this reference.

### TECHNICAL FIELD

The disclosure, in various embodiments, relates generally to the field of microelectronic device design and fabrication. More specifically, the disclosure relates to microelectronic devices including vertical channel access devices, and to related memory devices, electronic systems, and methods.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, volatile memory devices, such as dynamic random access memory (DRAM) devices; and non-volatile memory devices such as NAND Flash memory devices. A typical memory cell of a DRAM device includes one access device, such as a transistor, and one memory storage structure, such as a capacitor. Modern applications for semiconductor devices can employ significant quantities of memory cells, arranged in memory arrays exhibiting rows and columns of the memory cells. The memory cells may be electrically accessed through digit lines (e.g., bit lines, data lines) and word lines (e.g., access lines) arranged along the rows and columns of the memory cells of the memory arrays. Memory arrays can be two-dimensional (2D) so as to exhibit a single deck (e.g., a single tier, a single level) of the memory cells, or can be three-dimensional (3D) so as to exhibit multiple decks (e.g., multiple levels, multiple tiers) of the memory cells.

As the density and complexity of the memory array have increased, so has the complexity of the memory devices. In some instances, horizontally oriented access devices (e.g., horizontal channel access devices) for memory cells of a memory device consume more horizontal real estate within the memory device than is desirable, reducing the memory density of the memory device.

### BRIEF DESCRIPTION OF THE SEVERAL VIEWS OF THE DRAWINGS

FIG. 1A through FIG. 1H include simplified, partial vertical cross-sectional views of a microelectronic device structure at different processing stages of a method of forming a microelectronic device, according to one or more embodiments of the disclosure; and

FIG. 2 is a schematic block diagram of an electronic system, in accordance with an embodiment of the disclosure.

### DETAILED DESCRIPTION

The illustrations included herewith are not meant to be actual views of any particular systems, microelectronic structures, microelectronic devices, or integrated circuits thereof, but are merely idealized representations that are employed to describe embodiments herein. Elements and features common between figures may retain the same numerical designation except that, for ease of following the description, reference numerals begin with the number of the drawing on which the elements are introduced or most fully described.

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete process flow for manufacturing a microelectronic device (e.g., a semiconductor device, a memory device), apparatus, or electronic system, or a complete microelectronic device, apparatus, or electronic system. The structures described below do not form a complete microelectronic device, apparatus, or electronic system. Only those process acts and structures necessary to understand the embodiments described herein are described in detail below. Additional acts to form a complete microelectronic device, apparatus, or electronic system from the structures may be performed by conventional techniques.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

As used herein, the term “configured” refers to a size, shape, material composition, orientation, and arrangement of one or more of at least one structure and at least one apparatus facilitating operation of one or more of the structure and the apparatus in a predetermined way.

As used herein, the terms “longitudinal,” “vertical,” “lateral,” and “horizontal” are in reference to a major plane of a substrate (e.g., base material, base structure, base construction, etc.) in or on which one or more structures and/or features are formed and are not necessarily defined by Earth's gravitational field. A “lateral” or “horizontal” direction is a direction that is substantially parallel to the major plane of the substrate, while a “longitudinal” or “vertical” direction is a direction that is substantially perpendicular to the major plane of the substrate. The major plane of the substrate is defined by a surface of the substrate having a relatively large area compared to other surfaces of the substrate. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 113.0 percent of the numerical value, such as within a range of from 95.0 percent to 107.0 percent of the numerical value, within a range of from 97.5 percent to 101.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “proximate,” when utilized to describe positions of elements relative to each other, means that the elements are relatively close or near to each other. For example, where a first element is proximate a horizontal boundary of a second element, the first element is closer to that horizontal boundary than other horizontal boundaries of the second element.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “memory device” means and includes microelectronic devices exhibiting memory functionality, but not necessarily limited to memory functionality. Stated another way, and by way of example only, the term “memory device” means and includes not only conventional memory (e.g., conventional volatile memory, such as conventional DRAM; conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe-and Ni-based alloy, a Co- and Ni-based alloy, an Fe-and Co-based alloy, a Co- and Ni-and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including a conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In addition, an “insulative structure” means and includes a structure formed of and including an insulative material.

As used herein, the term “sacrificial material” means and includes a material that is formed and/or employed during a fabrication process but which is subsequently removed, in whole or in part, prior to completion of the fabrication process. A “partially-sacrificial” material means and includes a sacrificial material from which only one or more portions is or are removed prior to completion of the fabrication process. A “wholly-sacrificial” material means and includes a sacrificial material that is substantially entirely removed prior to completion of the fabrication process.

As used herein, “semiconductor material” and “semiconductive material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

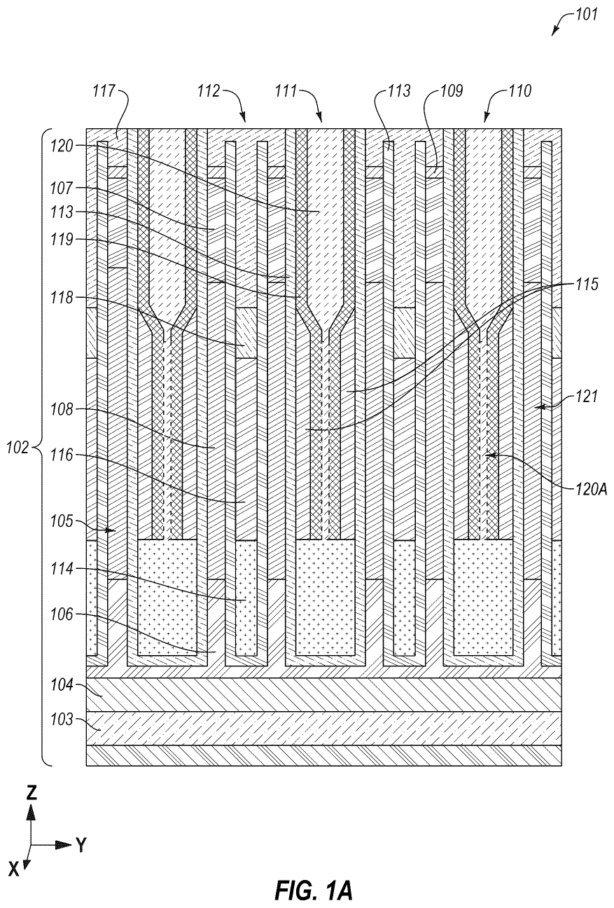

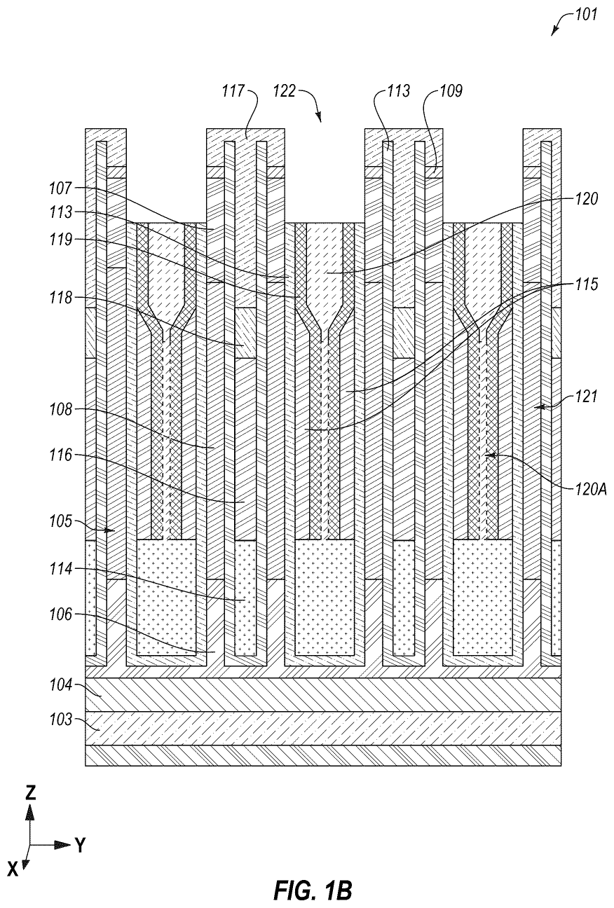

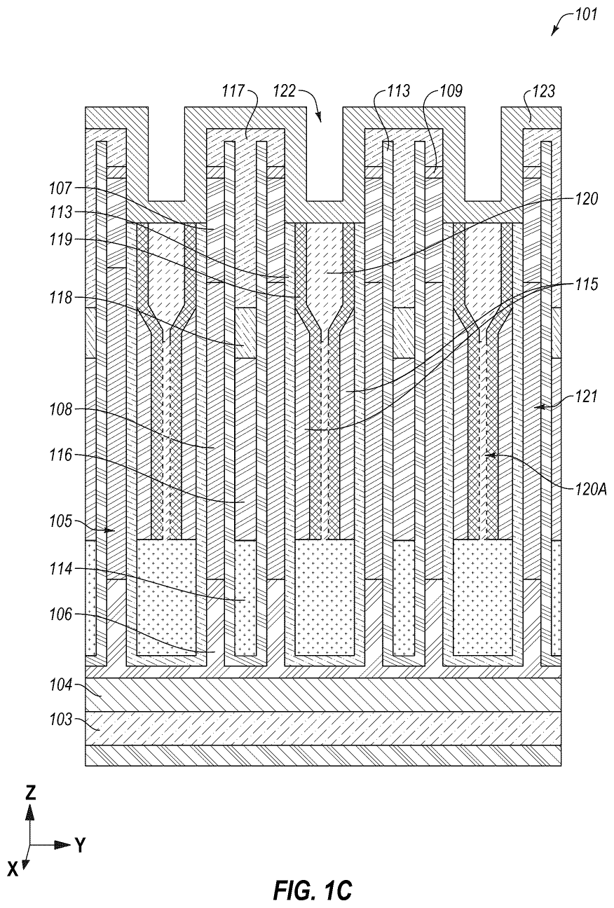

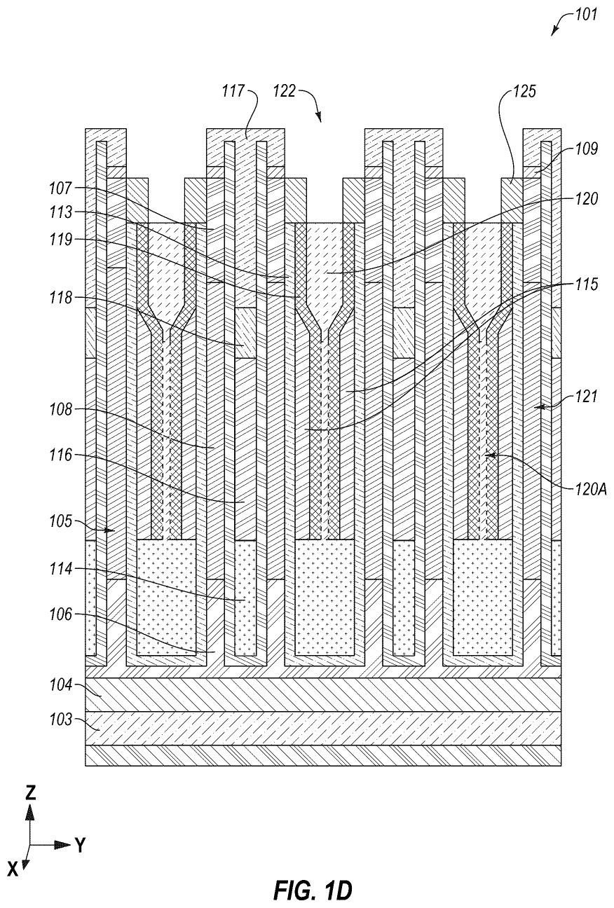

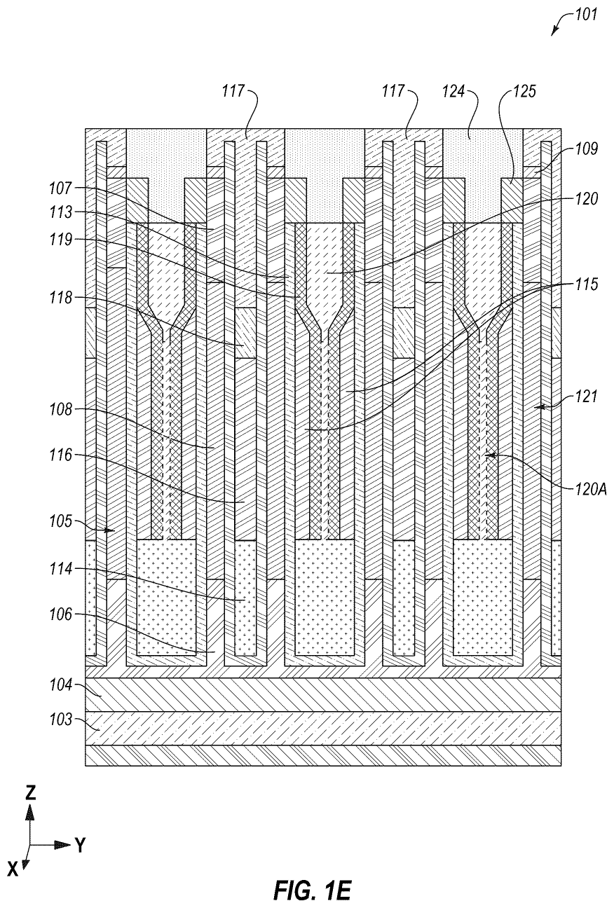

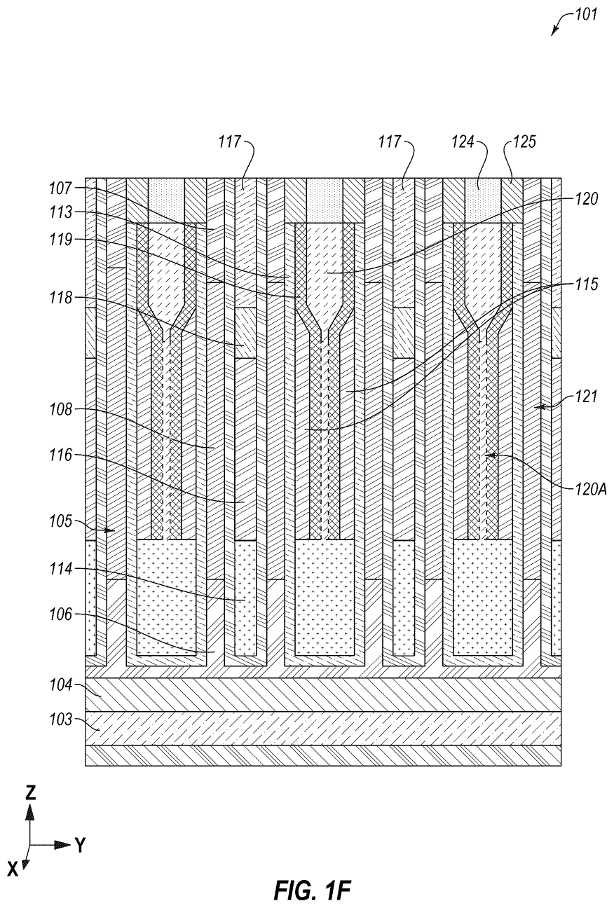

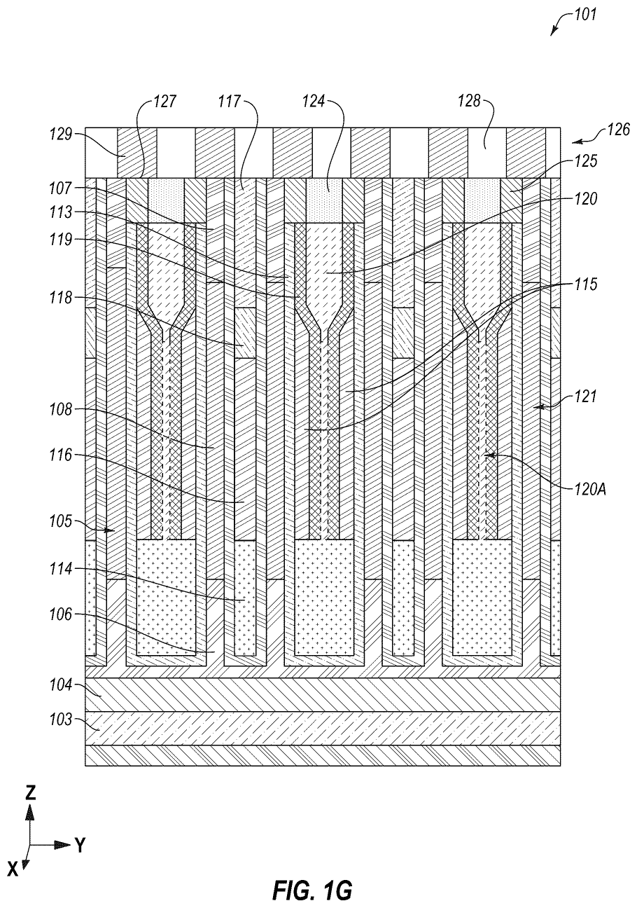

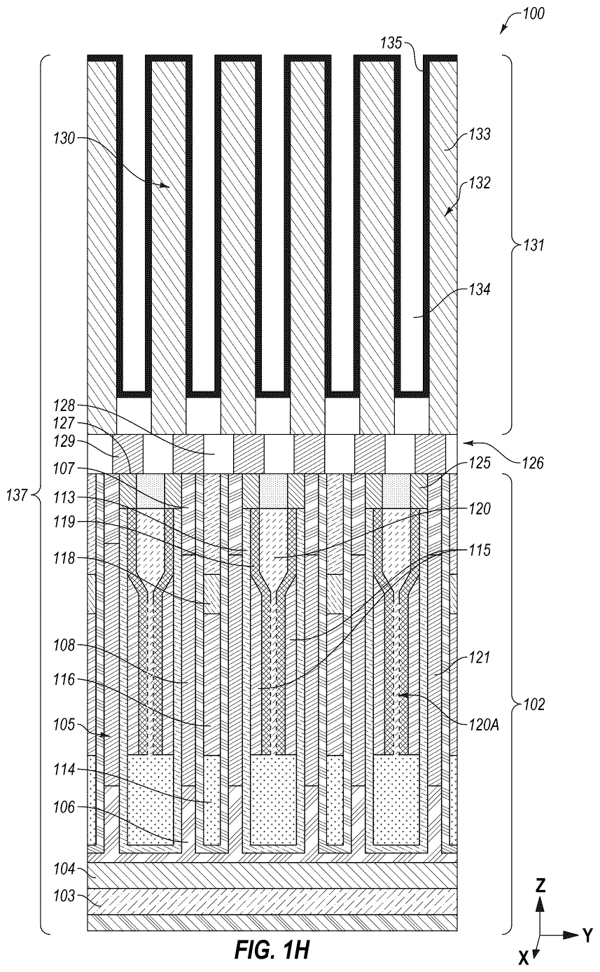

FIGS. 1A through 1H include simplified, partial vertical cross-sectional views of a microelectronic device structure 101 (e.g., a memory array structure) at different processing stages of a method of forming a microelectronic device (e.g., a memory device, such as Dynamic Random Access Memory (DRAM) device, an HRAM device, an FeRAM device, an SDRAM device, an MRAM device, etc.), in accordance with embodiments of the disclosure. With the description provided below, it will be readily apparent to one of ordinary skill in the art that the methods described herein may be used for forming various devices.

Referring to FIG. 1A, the microelectronic device structure 101 may be formed to include a first assembly 102. As described in further detail below, the first assembly 102 may include a base structure 103 (e.g., a silicon substrate), an etch stop structure 104 (e.g., a semiconductive etch stop structure, such as an SiGe structure; an insulative etch stop structure) on or over the base structure 103, and vertical channel access devices 121 (e.g., vertical channel transistors, vertical access devices) on or over the etch stop structure 104. The first assembly 102 also includes additional features (e.g., filled trenches, shield structures), as also described in further detail below.

In some embodiments, the base structure 103 includes a first semiconductor material (e.g., Si); and the etch stop structure 104 includes a second semiconductor material (e.g., SiGe) having etch selectivity relative to the first semiconductor material. In additional embodiments, the base structure 103 includes a semiconductor material and the etch stop structure 104 includes insulative material.

As described in further detail below, the vertical channel access devices 121 may respectively include a semiconductor pillar 105 defining a source region, a drain region, and a channel region vertically interposed between the source region and the drain region; a gate electrode 115 horizontally neighboring (e.g., in the Y-direction) the semiconductor pillar 105 and vertically overlapping (e.g., within a vertical extent in the Z-direction of) a channel region of the semiconductor pillar 105; and a gate dielectric material 113 horizontally interposed (e.g., in the Y-direction) between the semiconductor pillar 105 and the gate electrode 115. These features of the vertical channel access devices 121 are described in further detail below. The vertical channel access devices 121 may be arranged in an array including rows of the vertical channel access devices 121 horizontally extending in parallel in a first direction (e.g., the Y-direction), and columns of the vertical channel access devices 121 horizontally extending in parallel in a second direction (e.g., the X-direction) orthogonal to the first direction.

The semiconductor pillars 105 of the vertical channel access devices 121 may be formed to upwardly vertically extend from an upper surface of the etch stop structure 104. The semiconductor pillars 105 may respectively be formed of and include semiconductor material, such as epitaxial silicon material (e.g., silicon epitaxially grown on or over the etch stop structure 104). The semiconductor pillars 105 may be laterally spaced apart from one another by filled trenches (described in further detail below).

The semiconductor pillars 105 may respectively include a first doped region 106 vertically overlying the etch stop structure 104, an undoped region 108 vertically overlying the first doped region 106, and a second doped region 107 vertically overlying the undoped region 108. In some embodiments, each of the first doped region 106 and the second doped region 107 are N-type doped, such as N-type doped to an N-type dopant concentration within a range of from about 10¹⁵ cm⁻³ to about 10²⁰ cm⁻³. In additional embodiments, one of the first doped region 106 and the second doped region 107 may be N-type doped while the other of the first doped region 106 and the second doped region 107 may be P-type doped, such as P-type doped to a P-type dopant concentration within a range of from about −10¹³ cm⁻³ to about −10¹⁸ cm⁻³. In additional embodiments, one or more of the first doped region 106 is doped (either P-doped or N-doped) to the point of saturation (e.g., greater than or equal to about −10¹⁸ cm⁻³). The doping may be accomplished utilizing any suitable processing, such as by implanting dopant (e.g., at least one N-type dopant or at least one P-type dopant) into semiconductor material of the semiconductor pillars 105. A P-type dopant may include one or more of boron, aluminum, and gallium; and an N-type dopant may include one or more of arsenic, phosphorous, antimony, and bismuth.

In some embodiments, the undoped region 108 does not include any P-type dopants or any N-type dopants. In alternative embodiments, the undoped region 108 is doped with one of the dopants described herein and becomes another doped region. In such embodiments, a dopant type of the undoped region 108 is different than dopant types of the first doped region 106 and the second doped region 107. For example, if the first doped region 106 and the second doped region 107 respectively include semiconductor material (e.g., epitaxial silicon) doped with at least one N-type dopant, the undoped region 108 may include the semiconductor material (e.g., epitaxial silicon) doped with at least one P-type dopant.

For an individual semiconductor pillar 105, the first doped region 106 may form a drain region of the vertical channel access device 121 including the semiconductor pillar 105, the undoped region 108 may form a channel region of the vertical channel access device 121, and the second doped region 107 may form a source region of the vertical channel access device 121.

The microelectronic device structure 101 may further include insulative caps 109 formed on or over the second doped regions 107 of the semiconductor pillars 105. The insulative caps 109 may respectively be formed of and include insulative material. In some embodiments, the insulative caps 109 are respectively formed of and include dielectric nitride material, such as SiN_{y} (e.g., Si₃N₄).

Still referring to FIG. 1A, filled trenches, referred to herein as filled x-axis trenches 110, may be formed to vertically extend along (e.g., in the Z-direction) and horizontally separate semiconductor pillars 105 horizontally neighboring one another in the Y-direction. The filled x-axis trenches 110 may horizontally extend in parallel in the X-direction perpendicular to the Y-direction. In addition, further filled trenches, referred to herein as filled y-axis trenches, may extend horizontally in parallel in the Y-direction. The filled y-axis trenches vertically extend along (e.g., in the Z-direction) and horizontally separate semiconductor pillars 105 horizontally neighboring one another in the X-direction. In some embodiments, the filled x-axis trenches 110 and the filled y-axis trenches have vertical depths (e.g., vertical heights) within a range of from about 100 nm to about 200 nm (e.g., about 145 nm).

In one or more embodiments, some of the filled x-axis trenches 110 have larger widths in the Y-direction than others of the x-axis trenches 110. The filled x-axis trenches 110 having larger widths may be referred to as “wide filled x-axis trenches 111” hereinafter, and the x-axis trenches 110 having smaller widths may be referred to as “thin filled x-axis trenches 112” hereinafter. Furthermore, in some embodiments, each of the wide filled x-axis trenches 111 may be formed horizontally between, in the Y-direction, two (2) thin filled x-axis trenches 112.

The filled x-axis trenches 110 may respectively include the gate dielectric material 113 (e.g., dielectric liner material) formed on or over sidewalls (e.g., side surfaces) of the semiconductor pillars 105. The gate dielectric material 113 may substantially vertically extend across (e.g., may span entire vertical extents of) the semiconductor pillars 105. As shown in FIG. 1A, the gate dielectric material 113 may also cover sidewalls (e.g., side surfaces) of at least the insulative caps 109.

The gate dielectric material 113 may be formed of and include an insulative material. In some embodiments, the gate dielectric material 113 is formed of and includes silicon dioxide. In one or more embodiments, the gate dielectric material 113 includes a material with a relatively high dielectric constant (k) (e.g., a high-k material) as compared to silicon dioxide, such as a dielectric constant greater than about 3.9 (e.g., greater than or equal to 4, such as greater than or equal to 10, greater than or equal to 20, or greater than or equal to 25). The gate dielectric material 113 may have a thickness within a range of from about 4 nm to about 6 nm (e.g., about 5 nm).

The filled x-axis trenches 110 (including the wide filled x-axis trenches 111 and the thin filled x-axis trenches 112) may further respectively include a spacer material 114. The spacer material 114 may be positioned within bottom (e.g., vertically lower) regions of the filled x-axis trenches 110. The gate dielectric material 113 may cover sidewalls (e.g., side surfaces) of the spacer material 114. In some embodiments, the gate dielectric material 113 also substantially covers bottom surfaces of the spacer material 114.

The spacer material 114 may be formed of and include insulative material. In some embodiments, the spacer material 114 is formed of and includes dielectric oxide material, such as SiOₓ (e.g., SiO₂). The spacer material 114 may be substantially homogeneous, or the spacer material 114 may be heterogeneous. The spacer material 114 may, for example, be formed of and include a stack of at least two different dielectric materials.

The spacer material 114 may be formed to have upper boundaries facilitating desired vertical positioning (e.g., in the Z-direction) of the gate electrodes 115 within the wide filled x-axis trenches 111 and shield gate structures 116 (e.g., backgate structures) within the thin filled x-axis trenches 112. A vertical height of the spacer material 114 may permit the gate electrodes 115 and the shield gate structures 116 to vertically overlap the undoped region 108 (e.g., channel region) of respective ones of the semiconductor pillars 105. The vertical height of the spacer material 114 may at least partially determine a vertical distance between the gate electrodes 115 (and the shield gate structures 116) and later-formed digit lines. In some embodiments, the spacer material 114 has a vertical height within a range of from about 30 nm to about 60 nm, such as about 45 nm.

As mentioned briefly above, within the wide filled x-axis trenches 111, the gate electrodes 115 (e.g., gate structures) are vertically positioned on or over the spacer material 114. Portions of the gate dielectric material 113 vertically extend along gate electrodes 115 and are horizontally interposed in the Y-direction between the semiconductor pillars 105 and the gate electrodes 115. As shown in FIG. 1A, an individual wide filled x-axis trench 111 may include two (2) of the gate electrodes 115. The gate electrodes 115 may comprise portions of word line structures within the wide filled x-axis trenches 111 and respectively shared by multiple (e.g., a column) of the vertical channel access devices 121. The gate electrodes 115 may be formed of and include conductive material, such as one or more of tungsten (W), ruthenium (Ru), molybdenum (Mo), titanium (Ti), alloys thereof, and nitrides thereof.

Additionally, within the thin filled x-axis trenches 112, the shield gate structures 116 (also referred to herein as “back gate structures” or “word line (WL) shield structures”) are vertically positioned on or over the spacer material 114. Portions of the gate dielectric material 113 vertically extend along shield gate structures 116 and are horizontally interposed in the Y-direction between the semiconductor pillars 105 and shield gate structures 116. As shown in FIG. 1A, an individual thin filled x-axis trench 112 may include one (1) of the shield gate structures 116. Furthermore, the shield gate structures 116 may respectively be horizontally interposed between neighboring vertical channel access devices 121 in the Y-direction and may extend in parallel in the X-direction.

The shield gate structures 116 within the thin filled x-axis trenches 112 may shield the gate electrodes 115 (and the word line structures associated therewith) from cross-interference between gate electrodes 115 (and the word line structures associated therewith). For example, the shield gate structures 116 may control electrical field interference between the vertical channel access devices 121 including the semiconductor pillars 105. In some embodiments, the shield gate structures 116 are formed of and include conductive material, such as one or more of tungsten (W), ruthenium (Ru), molybdenum (Mo), titanium (Ti), alloys thereof, and nitrides thereof. In one or more embodiments, the shield gate structures 116 are formed of and include semiconductor material (e.g., polysilicon). Furthermore, the shield gate structures 116 may be operably connected to a respective voltage supply. During use and operation of a microelectronic device of the disclosure, the shield gate structures 116 may be employed to tune electrical properties of the vertical channel access devices 121. For example, the shield gate structures 116 may be employed to modify threshold voltages of the vertical channel access devices 121 and/or to reduce leakage current (enhancing control over the vertical channels of the vertical channel access devices 121).

As shown in FIG. 1A, within the thin filled x-axis trenches 112, interfacial material 118 may be formed to vertically overlie and horizontally overlap the shield gate structures 116. The interfacial material 118 may be formed of and include one or more of conductive material and semiconductor material. In one or more embodiments, the interfacial material 118 is formed and includes polysilicon, such as doped polysilicon (e.g., N-type doped polysilicon).

In addition, a dielectric capping structure 117 may respectively be formed on or over upper surfaces of the interfacial material 118 within an individual thin filled x-axis trench 112, as well as on or over upper surfaces of the insulative caps 109 and upper portions (e.g., upper surfaces, upper portions of sidewalls) of the gate dielectric material 113 horizontally neighboring (e.g., in the Y-direction) the thin filled x-axis trench 112. Portions of an individual dielectric capping structure 117 vertically overlie (e.g., in the Z-direction) and horizontally overlap (e.g., in the Y-direction and the X-direction) an individual shield gate structure 116 and at least two (2) semiconductor pillars 105 horizontally neighboring the shield gate structure 116 in the Y-direction. As shown in FIG. 1A, the wide filled x-axis trenches 111 may respectively be substantially free of any portions of the dielectric capping structures 117 within a horizontal area thereof. The dielectric capping structures 117 may respectively be formed of and include dielectric material, such as dielectric nitride material (e.g., silicon nitride).

In some embodiments, the wide filled x-axis trenches 111 are formed to further include additional dielectric liner material 119 on or over surfaces of the spacer material 114, the gate electrodes 115, and the gate dielectric material 113. The additional dielectric liner material 119 may be formed of and include insulative material. In some embodiments, the additional dielectric liner material 119 is formed of and includes one or more of dielectric oxide material, dielectric nitride material, dielectric oxynitride material, dielectric carboxy material, dielectric carbonitride material, and dielectric carboxynitride material. A material composition of the additional dielectric liner material 119 may be substantially the same as or different than a material composition of one or more of the spacer material 114 and the gate dielectric material 113. In additional embodiments, the wide filled x-axis trenches 111 are free of the additional dielectric liner material 119.

Still referring to FIG. 1A, the wide filled x-axis trenches 111 further respectively include first insulative material 120 over surfaces of the spacer material 114, the gate electrodes 115, the gate dielectric material 113, and the additional dielectric liner material 119 (if any) thereof. For an individual wide filled x-axis trench 111, the first insulative material 120 may vertically overlie the spacer material 114 and may horizontally extend between the two (2) gate electrodes 115 of the wide filled x-axis trench 111. The first insulative material 120 may also horizontally extend between opposing portions of the gate dielectric material 113. In some embodiments, for respective ones of the wide filled x-axis trenches 111, the first insulative material 120 vertically extends to and physically contacts the spacer material 114 of the wide filled x-axis trench 111. In additional embodiments, for respective ones of the wide filled x-axis trenches 111, the first insulative material 120 does not vertically extend to and physically contacts the spacer material 114 of the wide filled x-axis trench 111. Instead, for respective ones of the wide filled x-axis trenches 111, an air gap 120A (depicted by way of a dashed box in FIG. 1A) may be vertically interposed between an upper surface of the spacer material 114 and a lower surface of the first insulative material 120. Boundaries of the air gap 120A may be defined by the upper surface of the spacer material 114, the lower surface of the first insulative material 120, and inner side surfaces of the additional dielectric liner material 119 (if any) (or inner side surfaces of the gate electrodes 115 if the additional dielectric liner material 119 is absent). In addition, uppermost surfaces of the first insulative material 120, the dielectric capping structures 117, the gate dielectric material 113, and the additional dielectric liner material 119 (if any) may be formed to be substantially coplanar with one another.

Referring next to FIG. 1B, upper portions of the first insulative material 120, gate dielectric material 113, and additional dielectric liner material 119 (if any) within horizontal areas of the wide filled x-axis trenches 111 may be removed (e.g., etched) to form recesses 122 (e.g., openings). The recesses 122 may be substantially confined within horizontal areas of the wide filled x-axis trenches 111 and may respectively be formed to a desired depth (e.g., vertical dimension) in the Z-direction. The depth of the recesses 122 may be selected to result in a desired depth of later-formed structures (e.g., liner structures, spacer structures) therein, as discussed below.

Lower boundaries of the recesses 122 may be within vertical extents of the second doped region 107 of respective ones of the semiconductor pillars 105. The lower boundaries of the recesses 122 may be below uppermost boundaries of the second doped regions 107 of the semiconductor pillars 105 and at or above lowermost boundaries of the second doped regions 107 of the semiconductor pillars 105. In addition, side surfaces of the second doped regions 107 of the semiconductor pillars 105, side surfaces of the insulative caps 109, and side surfaces of the dielectric capping structures 117 may define horizontal boundaries (e.g., in the Y-direction) of the recesses 122.

The recesses 122 may be formed by selectively etching the first insulative material 120, the gate dielectric material 113, and the additional dielectric liner material 119 (if any) of the wide filled x-axis trenches 111. The etching process may remove portions of the first insulative material 120, the gate dielectric material 113, and the additional dielectric liner material 119 (if any) of the wide filled x-axis trenches 111 without significantly removing other exposed materials (e.g., the second doped regions 107 of the semiconductor pillars 105, the dielectric capping structures 117, and the insulative caps 109) of the microelectronic device structure 101.

Referring next to FIG. 1C, conductive contact material 123 (e.g., conductive interconnect material, conductive puck material, a conductive plug material) may be formed (e.g., conformally deposited) over exposed surfaces inside and outside of the recesses 122. The conductive contact material 123 may continuously extend across and cover surfaces of the second doped regions 107 of the semiconductor pillars 105, the insulative caps 109, the dielectric capping structures 117, the first insulative material 120, gate dielectric material 113, and additional dielectric liner material 119 (if any) defining boundaries of the recesses 122. In addition, the conductive contact material 123 may continuously extend across and cover upper surfaces of the dielectric capping structures 117 outside of the horizontal areas of the recesses 122.

The conductive contact material 123 may only partially (e.g., less than completely) fill the recesses 122. Horizontally central portions of the recesses 122 in the Y-direction remain partially unfilled by the conductive contact material 123. A thickness of the conductive contact material 123 may be selected to impart desired horizontal dimensions to remaining (e.g., unfilled) portions of the recesses 122. A thickness of the conductive contact material 123 may, for example, be at least as thick as a thickness of the gate dielectric material 113. As shown in FIG. 1C, in some embodiments, a thickness of the conductive contact material 123 is substantially equal to a combined thickness of the gate dielectric material 113, and additional dielectric liner material 119. In additional embodiments, a thickness of the conductive contact material 123 is greater than the thickness of the gate dielectric material 113 but less than the combined thickness of the gate dielectric material 113, and additional dielectric liner material 119. In some embodiments, the conductive contact material 123 is formed to have a thickness within a range of from about 2 nm to about 10 nm, such as from about 3 nm to about 8 nm, from about 4 nm to about 7 nm, or about 5 nm.

The conductive contact material 123 may be formed of and include conductive material, such as one or more of a metal, an alloy, a conductive metal-containing material (e.g., a conductive metal nitride, a conductive metal silicide, a conductive metal carbide, a conductive metal oxide), and a conductively-doped semiconductor material (e.g., conductively-doped Si, conductively-doped Ge, conductively-doped SiGe). In some embodiments, the conductive contact material 123 is formed of and includes a metal material, such as one or more of W, Ru, Mo, Ti, alloys thereof, nitrides thereof, and silicides thereof. In additional embodiments, the conductive contact material 123 is formed of and includes conductively-doped semiconductor material, such an N-type doped silicon material (e.g., N-type doped polysilicon).

With reference to FIG. 1D, portions of the conductive contact material 123 (FIG. 1C) within and outside of the recesses 122 may be removed (e.g., etched) to form conductive contact structures 125 (e.g., conductive interconnect structures, conductive puck structures, conductive plug structures). The conductive contact material 123 (FIG. 1C) may be substantially removed from outside of the recesses 122; and may also be removed from horizontally central (e.g., in the Y-direction), bottom potions of the recesses 122 and upper portions of the recesses 122. The conductive contact structures 125 may be substantially confined within the recesses 122 (and, hence, within horizontal areas of the wide filled x-axis trenches 111). As shown in FIG. 1D, the conductive contact structures 125 may contact (e.g., directly physically contact) sidewalls (e.g., side surfaces) of the second doped regions 107 of the semiconductor pillars 105. Each of the conductive contact structures 125 may have a sidewall (e.g., a side surface) in physical contact with a sidewall (e.g., a side surface) of the second doped regions 107 of a respective one of the semiconductor pillars 105. Accordingly, the conductive contact structures 125 may be considered lateral contact structures.

For an individual conductive contact structure 125, an upper surface thereof may be formed to be vertically below upper surfaces of the dielectric capping structures 117, such as below upper surfaces of the insulative caps 109. In some embodiments, the upper surface of an individual conductive contact structure 125 is formed to be vertically positioned at or below an upper surface of the second doped region 107 of the semiconductor pillar 105 in contact with the conductive contact structure 125. For example, as shown in FIG. 1D, upper surfaces of the conductive contact structure 125 may be formed to be substantially coplanar with upper surfaces of the second doped regions 107 of the semiconductor pillars 105 of the vertical channel access devices 121. In additional embodiments, upper surfaces of an individual conductive contact structure 125 are formed to be vertically offset from (e.g., vertically above, vertically below) an upper surface of the second doped region 107 of the semiconductor pillar 105 in contact with the conductive contact structure 125.

In addition, within the horizontal area of an individual recess 122, an upper surface of the first insulative material 120 partially defining a lower boundary of the recess 122 may be exposed between two (2) of the conductive contact structures 125. Namely, the two (2) of the conductive contact structures 125 may be formed to be separate and discrete from one another within the recess 122.

In some embodiments, the conductive contact structures 125 respectively exhibit a vertical height (i.e., in the Z-direction) within a range of from about 2 nm to about 20 nm, such as from about 5 nm to about 15 nm, from about 7 nm to about 12 nm, or about 10 nm. In addition, in some embodiments, the conductive contact structures 125 exhibit a horizontal width in the Y-direction within a range of from about 2 nm to about 10 nm, such as from about 3 nm to about 8 nm, from about 4 nm to about 7 nm, or about 5 nm.

The conductive contact structures 125 may be formed from the conductive contact material 123 (FIG. 1C) using various material removal techniques, such as by a directional, selective etch process (e.g., an anisotropic etch process, such as an anisotropic dry or wet etch process) that removes portions of the conductive contact material 123 (FIG. 1C) without significantly removing other materials (e.g., the first insulative material 120, the dielectric capping structures 117, and the insulative cap 109) of the microelectronic device structure 101. Forming the conductive contact structures 125 from the conductive contact material 123 (FIG. 1C) in the manner described herein advantageously permits the conductive contact structures 125 to be self-aligned relative to the second doped regions 107 of the semiconductor pillars 105 in contact therewith. The conductive contact structures 125 are also individually self-aligned relative to the gate electrode 115 of a respective one of the vertical channel access devices 121 operatively associated therewith.

Referring next to FIG. 1E, a spacer material 124 may be formed (e.g., deposited, such as non-conformally deposited) within remaining (e.g., unfilled) portions of the recesses 122 (FIG. 1D). The spacer material 124 may substantially fill the remaining portions of the recesses 122 (FIG. 1D). Within horizontal areas and vertical spans of the recesses 122 (FIG. 1D), the spacer material 124 may cover surfaces of the first insulative material 120, the additional dielectric liner material 119 (if any), the conductive contact structures 125, the insulative caps 109, and the dielectric capping structures 117.

The spacer material 124 may be formed of and include insulative material, such as one or more of dielectric oxide material, dielectric nitride material, dielectric oxynitride material, dielectric carboxy material, dielectric carbonitride material, and dielectric carboxynitride material. In some embodiments, the spacer material 124 is formed of and includes a spin-on dielectric material (e.g., a spin-on oxide material, a spin-on nitride material) formed by a spin coating process. The spacer material 124 may, optionally, be subjected to an annealing process (e.g., a thermal annealing process, a laser annealing process) following initial formation (e.g., deposition) thereof.

As shown in FIG. 1D, the spacer material 124 may be formed to have upper surfaces substantially coplanar with (e.g., substantially extensive with) upper surfaces of remaining positions of the dielectric capping structures 117. A CMP process may, for example, be used to form the substantially coplanar upper surfaces of the spacer material 124 and the dielectric capping structures 117.

Referring to FIG. 1F, portions of the dielectric capping structures 117, the spacer material 124, the insulative caps 109, the gate dielectric material 113, and the conductive contact structures 125 above upper boundaries (e.g., upper surfaces) of the second doped regions 107 of the semiconductor pillars 105 may be removed while substantially maintaining additional portions thereof below the upper boundaries of the second doped regions 107 of the semiconductor pillars 105. For example, the portions of the dielectric capping structures 117, the spacer material 124, the insulative caps 109, the gate dielectric material 113, and the conductive contact structures 125 above the upper boundaries (e.g., upper surfaces) of the second doped regions 107 of the semiconductor pillars 105 may be removed by way of a CMP process. In some embodiments, uppermost portions of the second doped regions 107 of the semiconductor pillars 105 are also removed by way of the removal process, along with corresponding portions of the conductive contact structures 125. Following the removal process, upper surfaces of remaining portions of the dielectric capping structures 117, the gate dielectric material 113, the second doped regions 107 of the semiconductor pillars 105, the conductive contact structures 125, and the spacer material 124 are exposed. The exposed upper surfaces of conductive contact structures 125 and the second doped regions 107 of the semiconductor pillars 105 may together form interface areas 127 (e.g., interface surfaces, landing surfaces, landing areas) for later-formed redistribution material (RDM) structures (also referred to as redistribution layer (RDL) structures), as described in further detail below with reference to FIG. 1G. The interface areas 127 may individually include an upper surface of one of the conductive contact structures 125 and an upper surface of the second doped region 107 of one of the semiconductor pillars 105 in contact (e.g., lateral contact) with the one of the conductive contact structures 125. The interface areas 127 may be relatively more symmetrically distributed relative to convention interface areas formed by conductive contact structures formed to vertically overlie the second doped regions of the semiconductor pillars in contact therewith.

Referring next to FIG. 1G, a RDL tier 126 including RDM structures 129 and isolation material 128 horizontally interposed (e.g., in the Y-direction, in the X-direction) may be formed over the exposed surfaces of second doped regions 107 of the semiconductor pillars 105, the dielectric capping structures 117, the gate dielectric material 113, the conductive contact structures 125, and the spacer material 124. The RDM structures 129 of the RDL tier 126 may individually be formed to contact (e.g., physically contact) a respective one of the interface areas 127 (as individually defined by the upper surface of one of the conductive contact structures 125 and the upper surface of the second doped region 107 of one of the semiconductor pillars 105 in contact with the one of the conductive contact structures 125).

The RDM structures 129 of the RDL tier 126 may facilitate a horizontal arrangement (e.g., a hexagonal close packed arrangement) of storage node devices (e.g., capacitors) (described below) thereover that is different than a horizontal arrangement of the semiconductor pillars 105 of the vertical channel access devices 121 thereunder. The RDM structures 129 may individually physically contact the upper surface of one of the second doped region 107 of one of the semiconductor pillars 105, the upper surface of one of the conductive contact structures 125, or upper surfaces of both of one of the conductive contact structures 125 and the second doped region 107 of one of the semiconductor pillars 105. The RDM structures 129 may be horizontally positioned (e.g., in the X-direction, in the Y-direction) differently relative to respective ones of the interface area 127 than one another. For example, as shown in FIG. 1G, one or more of the RDM structures 129 may individually have a horizontal center in the Y-direction that is at or relatively more proximate a horizontal center in the Y-direction of a respective one of the conductive contact structures 125, while one or more others of the RDM structures 129 may individually have a horizontal center in the Y-direction that is at or relatively more proximate a horizontal center in the Y-direction of the second doped region 107 of a respective one of the semiconductor pillars 105. The horizontally positioning the conductive contact structures 125 relative to the second doped regions 107 of one of the semiconductor pillars 105 through the methods of the disclosure may mitigate misalignment of the RDM structures 129 as compared to conventional methods and configurations employing conventional, non-self-aligned conductive contact structures that are formed vertically between and in contact with semiconductor pillars and RDM structures.

The RDM structures 129 of the RDL tier 126 may respectively be formed of and include conductive material. In some embodiments, the RDM structures 129 of the RDL tier 126 are respectively formed of and include one or more of W, Ru, Mo, Ti, alloys thereof, nitrides thereof, and silicides thereof. In addition, the isolation material 128 of the RDL tier 126 may be formed of and include dielectric material. In some embodiments, the isolation material 128 of the RDL tier 126 is formed of and include dielectric oxide material (e.g., SiOₓ, such as SiO₂).

Referring next to FIG. 1H, a multi-storage node structure 131 including multiple storage node devices 130 (e.g., capacitors) may be formed on or over the RDL tier 126 and the RDM structures 129 to form a second assembly 137. The storage node devices 130 are coupled to the RDM structures 129, and, hence, with the vertical channel access devices 121. The storage node devices 130, the vertical channel access devices 121, the RDM structures 129, and the conductive contact structures 125 may together form memory cells 132 (e.g., DRAM cells) of a microelectronic device 100 (e.g., memory device, such as DRAM device) of the disclosure. An individual memory cell 132 may include one of the vertical channel access devices 121, one of the storage node devices 130, one of the contact structures 125, and one of the RDM structures 129 extending from the one of the storage node devices 130 to upper surfaces of the one of the vertical channel access devices 121 (the second doped region 107 of the semiconductor pillar 105 thereof) and the one of the contact structures 125. The storage node devices 130 may individually be formed and configured to store a charge representative of a programmable logic state of the memory cell 132 including the storage node device 130.

In some embodiments, the storage node devices 130 include capacitors. During use and operation, a charged capacitor may represent a first logic state, such as a logic 1; and an uncharged capacitor may represent a second logic state, such as a logic 0. Each of the storage node devices 130 may, for example, be formed to include a first electrode 133 (e.g., a bottom electrode), a second electrode 134 (e.g., a top electrode), and a first dielectric material 135 between the first electrode 133 and the second electrode 134. For instance, each of the storage node devices 130 may include a metal-insulator-metal (MIM) capacitor. As another example, each of the storage node devices 130 may include a metal-insulator-semiconductor (MIS) capacitor. The collection of memory cells 132 may form a memory array.

The multi-storage node structure 131 may further include a conductive material formed between neighboring storage node devices 130. The conductive material may substantially cover and surround the storage node devices 130. The second electrode 134 of the storage node devices 130 may be operatively positioned (e.g., embedded) within the conductive material. The conductive material may include any of the conductive materials described herein. For instance, the conductive material may include polysilicon or conductively-doped silicon germanium (SiGe).

Following the formation of the multi-storage node structure 131, the second assembly 137 may be vertically inverted (e.g., flipped in the Z-direction), the base structure 103 and the etch stop structure 104 may be removed to expose the first doped regions 106 of the semiconductor pillars 105, and then digit line structures (e.g., data line structures, bit line structures) may be formed in contact (e.g., physical contact, electrical contact) with the first doped regions 106 of the semiconductor pillars 105. The digit line structures may horizontally extend in parallel in the Y-direction, and may be horizontally separated from one another in the X-direction. An individual digit line structure may be coupled to a group (e.g., a row) of the semiconductor pillars 105 (and, hence, a group of the vertical channel access devices 121, and a group of the memory cells 132). Different digit line structures may be coupled to different groups of the semiconductor pillars 105 (and, hence, different groups of the vertical channel access devices 121, and different groups of the memory cells 132) than one another. The digit line structures may respectively be formed of and include conductive material.

Thus, in accordance with some embodiments of the disclosure, a microelectronic device includes a vertical channel access device including a semiconductor pillar including a first doped region, a channel region vertically above the first doped region, and a second doped region vertically above the channel region. The vertical channel access device further includes a gate electrode horizontally offset from and vertically overlapping the channel region of the semiconductor pillar, and a gate dielectric material horizontally interposed between the gate electrode and the semiconductor pillar. The microelectronic device further includes a conductive contact structure at a vertical position of the second doped region of the semiconductor pillar of the vertical channel access device, the conductive contact structure physically contacting a side surface of the second doped region of the semiconductor pillar.

Moreover, in accordance with some embodiments of the disclosure, a method of forming a microelectronic device includes forming vertical channel access devices horizontally separated from one another by a filled trench containing gate electrodes for the vertical channel access devices, removing upper portions of the filled trench to form a recess exposing side surfaces of doped regions of semiconductor pillars of the vertical channel access devices, forming conductive contact structures within the recess, the conductive contact structures in physical contact with the side surfaces of the doped regions of the semiconductor pillars of the vertical channel access devices, and forming additional conductive structures on interface surfaces defined by upper surfaces of the conductive contact structures and the doped regions of the semiconductor pillars of the vertical channel access devices.

Additionally, in accordance with some embodiments of the disclosure, a memory device includes a memory cell including a vertical channel access device including a channel region vertically interposed between the two source/drain regions, a gate electrode horizontally offset from and vertically overlapping the channel region, and a gate dielectric material horizontally interposed between the channel region and the gate electrode and vertically overlapping the channel region and at least part of the two source/drain regions. The memory device further includes a conductive contact structure directly physically contacting and confined within a vertically extent of a side surface of one of the two source/drain regions, a conductive redistribution layer structure vertically above and physically contacting an at least one of an upper surface of the conductive contact structure and an upper surface of the one of the two source/drain regions, and a storage node device vertically above and coupled to the conductive redistribution layer structure.

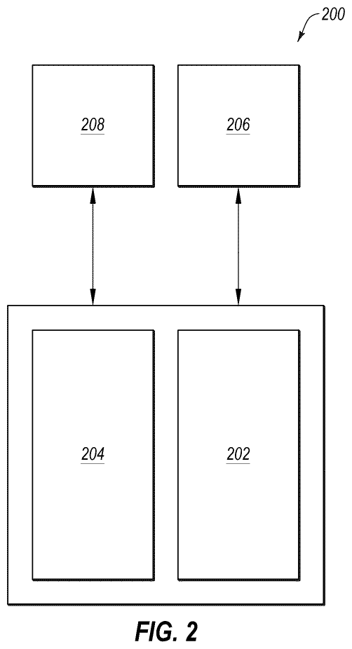

Microelectronic devices (e.g., the microelectronic device 100 (FIG. 1H)) in accordance with embodiments of the disclosure may be used in embodiments of electronic systems of the disclosure. For example, FIG. 2 is a block diagram illustrating an electronic system 200 according to embodiments of disclosure. The electronic system 200 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 200 includes at least one memory device 202. The memory device 202 may comprise, for example, a microelectronic device (e.g., the microelectronic device 100 (FIG. 1H)) previously described herein. The electronic system 200 may further include at least one electronic signal processor device 204 (often referred to as a “microprocessor”). The electronic signal processor device 204 may, optionally, comprise a microelectronic device (e.g., the microelectronic device 100 (FIG. 1H)) previously described herein. While the memory device 202 and the electronic signal processor device 204 are depicted as two (2) separate devices in FIG. 2, in additional embodiments, a single (e.g., only one) memory/processor device having the functionalities of the memory device 202 and the electronic signal processor device 204 is included in the electronic system 200. In such embodiments, the memory/processor device may include a microelectronic device (e.g., the microelectronic device 100 (FIG. 1H)) previously described herein. The electronic system 200 may further include one or more input devices 206 for inputting information into the electronic system 200 by a user, such as, for example, a mouse or other pointing device, a keyboard, a touchpad, a button, or a control panel. The electronic system 200 may further include one or more output devices 208 for outputting information (e.g., visual or audio output) to a user such as, for example, a monitor, a display, a printer, an audio output jack, a speaker, etc. In some embodiments, the input device 206 and the output device 208 comprise a single touchscreen device that can be used both to input information to the electronic system 200 and to output visual information to a user. The input device 206 and the output device 208 may communicate electrically with one or more of the memory device 202 and the electronic signal processor device 204.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure. Various modifications of the disclosure, in addition to those shown and described herein, such as alternate useful combinations of the elements and features described will become apparent to those skilled in the art from the description. Such modifications and embodiments also fall within the scope of the appended claims and equivalents.

What is claimed is:

1. A microelectronic device, comprising:
a vertical channel access device comprising:
a semiconductor pillar comprising:
a first doped region;
a channel region vertically above the first doped region; and
a second doped region vertically above the channel region;
a gate electrode horizontally offset from and vertically overlapping the channel region of the semiconductor pillar; and
a gate dielectric material horizontally interposed between the gate electrode and the semiconductor pillar; and
a conductive contact structure at a vertical position of the second doped region of the semiconductor pillar of the vertical channel access device, the conductive contact structure physically contacting a side surface of the second doped region of the semiconductor pillar.

2. The microelectronic device of claim 1, wherein an upper surface of the conductive contact structure is substantially coplanar with an upper surface of the second doped region of the semiconductor pillar of the vertical channel access device.

3. The microelectronic device of claim 1, wherein a vertical span of the conductive contact structure is less than that of the second doped region of the semiconductor pillar of the vertical channel access device.

4. The microelectronic device of claim 1, wherein a lower surface of the conductive contact structure physically contacts an upper surface of the gate dielectric material of the vertical channel access device.

5. The microelectronic device of claim 1, wherein the conductive contact structure at least partially horizontally overlaps the gate electrode of the vertical channel access device.

6. The microelectronic device of claim 1, further comprising an additional conductive structure on an interface surface defined by an upper surface of the conductive contact structure and an upper surface of the second doped region of the semiconductor pillar of the vertical channel access device.

7. The microelectronic device of claim 6, further comprising a storage node device vertically above and coupled to the additional conductive structure.

8. A method of forming a microelectronic device, comprising:
forming vertical channel access devices horizontally separated from one another by a filled trench containing gate electrodes for the vertical channel access devices;
removing upper portions of the filled trench to form a recess exposing side surfaces of doped regions of semiconductor pillars of the vertical channel access devices;
forming conductive contact structures within the recess, the conductive contact structures in physical contact with the side surfaces of the doped regions of the semiconductor pillars of the vertical channel access devices; and
forming additional conductive structures on interface surfaces defined by upper surfaces of the conductive contact structures and the doped regions of the semiconductor pillars of the vertical channel access devices.

9. The method of claim 8, wherein forming conductive contact structures within the recess comprises:
conformally depositing conductive liner material continuously extending inside and outside of the recess; and
removing portions of the conductive liner material outside of the trench and at a bottom of the trench to form the conductive contact structures.

10. The method of claim 8, wherein forming conductive contact structures within the recess comprises forming the conductive contact structures to at least partially horizontally overlap gate electrodes of the vertical channel access devices.

11. The method of claim 8, wherein forming conductive contact structures within the recess comprises forming the conductive contact structures to have vertical dimensions less than additional vertical dimensions of upper conductively doped regions of semiconductor pillars of the vertical channel access devices.

12. The method of claim 11, wherein forming conductive contact structures within the recess further comprises forming upper surfaces of the conductive contact structures to be substantially coplanar with additional upper surfaces of the upper conductively doped regions of the semiconductor pillars of the vertical channel access devices.

13. The method of claim 11, wherein forming additional conductive structures on interface surfaces comprises:
forming some of the additional conductive structures to at least physically contact the upper surfaces of the conductive contact structures; and
forming some others of the additional conductive structures to at least physically contact additional upper surfaces of the doped regions of the semiconductor pillars of the vertical channel access devices.

14. The method of claim 8, further comprising forming insulative structures within the recess and horizontally between the conductive contact structures before forming the additional conductive structures.

15. The method of claim 8, further comprising forming storage node devices vertically over and coupled to the additional conductive structures.

16. A memory device, comprising:
a memory cell comprising:
a vertical channel access device comprising:
a channel region vertically interposed between two source/drain regions;
a gate electrode horizontally offset from and vertically overlapping the channel region; and
a gate dielectric material horizontally interposed between the channel region and the gate electrode and vertically overlapping the channel region and at least part of the two source/drain regions;
a conductive contact structure directly physically contacting and confined within a vertical extent of a side surface of one of the two source/drain regions;
a conductive redistribution layer structure vertically above and physically contacting an at least one of an upper surface of the conductive contact structure and an upper surface of the one of the two source/drain regions; and
a storage node device vertically above and coupled to the conductive redistribution layer structure.

17. The memory device of claim 16, wherein the conductive contact structure horizontally overlaps each of the gate electrode and the gate dielectric material of the vertical channel access device.

18. The memory device of claim 16, wherein the conductive contact structure exhibits a vertical height within a range of from about 2 nm to about 20 nm.

19. The memory device of claim 16, further comprising dielectric liner material continuously extending over outer side surfaces of the gate electrode and the gate dielectric material, the conductive contact structure partially horizontally overlapping the dielectric liner material.

20. The memory device of claim 16, wherein the memory cell comprises a dynamic random access memory (DRAM) cell.
